(19) United States
(12) Patent Application Publication
(10) Pub. No.: US 2025/0014871 A1
(43) Pub. Date: Jan. 9, 2025

(54) SEMICONDUCTOR PROCESSING APPARATUS USING PLASMA

(71) Applicant: Samsung Electronics Co., Ltd., Suwon-si (KR)

(72) Inventors: Sungwon CHO, Suwon-si (KR); Kyunghyun KIM, Suwon-si (KR); Ingi KIM, Suwon-si (KR); Sangki NAM, Suwon-si (KR); Dougyong SUNG, Suwon-si (KR); Sejin OH, Suwon-si (KR); Sungho JANG, Suwon-si (KR)

(73) Assignee: Samsung Electronics Co., Ltd., Suwon-si (KR)

(21) Appl. No.: 18/406,898

(22) Filed: Jan. 8, 2024

(30) Foreign Application Priority Data
Jul. 7, 2023 (KR) 10-2023-0088295

(51) Int. Cl. H01J 37/32; H01L 21/683

(52) U.S. Cl. CPC H01J 37/32568; H01J 37/32715; H01L 21/6833; H01J 37/32082; H01J 2237/2007

(57) ABSTRACT

According to an aspect of the present inventive concepts, a semiconductor processing apparatus includes: a chamber; an electrostatic chuck in an internal space of the chamber; a plurality of grid electrodes installed on the electrostatic chuck so as to be separated from each other in a first direction, perpendicular to an upper surface of the electrostatic chuck, and respectively having a plurality of through-holes; a plurality of reflectors between the plurality of grid electrodes and the electrostatic chuck and reflecting ions passing through the plurality of through-holes in each of the plurality of grid electrodes; and a voltage supply unit outputting a bias voltage having a predetermined cycle to at least one of the plurality of grid electrodes, wherein each of the plurality of grid electrodes includes a base plate containing a conductive material, and a cover layer covering a surface of the base plate and containing a metal oxide.

### CROSS-REFERENCE TO RELATED APPLICATION(S)

This application claims benefit of priority to Korean Patent Application No. 10-2023-0088295, filed on Jul. 7, 2023 in the Korean Intellectual Property Office, the entire contents of which are incorporated herein by reference in their entirety.

### BACKGROUND

The present inventive concepts relate to a semiconductor processing apparatus using plasma.

In a semiconductor processing apparatus performing a semiconductor process using plasma, a beam may be generated by accelerating ions in a plasma state, and a neutral beam may be generated by neutralizing the ionized beam. The neutral beam may be generated, for example, when ions accelerated by a grid electrode collide with a reflector to exchange charges, and the ions may pass through a plurality of through-holes included in the grid electrode and move to the reflector. While the ions pass through the plurality of through-holes, the ions may collide with the grid electrode, and particles may be separated from the grid electrode by the collision with the ions. In these cases, the particles separated from the grid electrode in this manner may result in combination of the processed semiconductor and may therefor cause a decrease in yield of the semiconductor process.

### SUMMARY

An aspect of the present inventive concepts is to improve yield in a semiconductor process, and improve reliability and lifespan of a semiconductor processing apparatus, by minimizing a phenomenon in which particles are separated from a grid electrode or through-holes of the grid electrode are narrowed, due to the collision of ions and grid electrodes.

According to an aspect of the present inventive concepts, a semiconductor processing apparatus may include: a chamber defining an internal space; an electrostatic chuck included in the internal space of the chamber; a plurality of grid electrodes above the electrostatic chuck, the plurality of grid electrodes spaced apart from each other in a vertical direction and respectively having a plurality of through-holes; a plurality of reflectors between the plurality of grid electrodes and the electrostatic chuck, the plurality of reflectors configured to reflect ions passing through the plurality of through-holes of each of the plurality of grid electrodes; and at least one voltage supply configured to output a bias voltage having a cycle to at least one of the plurality of grid electrodes, wherein each of the plurality of grid electrodes includes a base plate comprising a conductive material, and a cover layer covering a surface of the base plate and comprising a metal oxide.

According to an aspect of the present inventive concepts, a semiconductor processing apparatus may include: an electrostatic chuck included in an internal space of a chamber; a beam source including a head defining a plasma space configured for process gas to be supplied to, a bias electrode on the head and configured to receive radio frequency (RF) power, and at least one grid electrode below the head, the at least one grid electrode each having a plurality of through-holes; and a gas supply configured to supply the process gas to the beam source, wherein the at least one grid electrode includes a base plate comprising a first material having conductivity, and a cover layer covering a surface of the base plate and comprising a second material, different from the first material.

According to an aspect of the present inventive concepts, a semiconductor processing apparatus may include: an electrostatic chuck included in an internal space of a chamber, a beam source including a head defining a plasma space configured for process gas to be supplied to, a bias electrode on the head and configured to receive radio frequency (RF) power, and a plurality of grid electrodes below the head, the plurality of grid electrodes each respectively including a plurality of through-holes; a gas supply configured to supply the process gas; and at least one voltage supply configured to supply, to each of the plurality of grid electrodes, a bias voltage, wherein the voltage supply is configured to supply a voltage having a cycle to at least one of the plurality of grid electrodes, and to supply a constant voltage to another of the plurality of grid electrodes.

### BRIEF DESCRIPTION OF DRAWINGS

The above and other aspects, features, and advantages of the present disclosure will be more clearly understood from the following detailed description, taken in conjunction with the accompanying drawings:

FIG. 1 is a diagram schematically illustrating a semiconductor processing system according to at least one example embodiment of the present inventive concepts;

FIG. 2 is a diagram schematically illustrating a semiconductor processing apparatus according to at least one example embodiment of the present inventive concepts;

FIGS. 3 and 4 are diagrams provided to illustrate an operation of a semiconductor processing apparatus according to at least one example embodiment of the present inventive concepts;

FIG. 5 is a diagram schematically illustrating a beam source included in a semiconductor processing apparatus according to at least one example embodiment of the present inventive concepts;

FIGS. 6 and 7 are diagrams schematically illustrating a grid electrode according to at least one example embodiment of the present inventive concepts;

FIGS. 8 and 9 are diagrams provided to illustrate an operation of a semiconductor processing apparatus according to at least one example embodiment of the present inventive concepts;

FIGS. 10 and 11A through 11C are diagrams provided to illustrate an operation of a semiconductor processing apparatus according to at least one example embodiment of the present inventive concepts;

FIGS. 12 to 14 are diagrams provided to illustrate an operation of a semiconductor processing apparatus according to at least one example embodiment of the present inventive concepts;

FIGS. 15 and 16A through 16B are diagrams provided to illustrate an operation of a semiconductor processing apparatus according to at least one example embodiment of the present inventive concepts; and

FIG. 17 is a diagram provided to illustrate an operation of a semiconductor processing apparatus according to at least one example embodiment of the present inventive concepts.

### DETAILED DESCRIPTION

Hereinafter, some example embodiments of the present inventive concepts will be described with reference to the accompanying drawings. The example embodiments, however, may be embodied in various different forms, and should not be construed as being limited to only the illustrated embodiments. Unless otherwise noted, like reference characters denote like elements throughout the attached drawings and written description, and thus descriptions will not be repeated.

When the terms “about” or “substantially” are used in this specification in connection with a numerical value, it is intended that the associated numerical value includes a manufacturing tolerance (e.g., ±10%) around the stated numerical value. Moreover, when the words “similar” and “substantially” are used in connection with composition and/or geometric shapes, it is intended that precision of composition and/or the geometric shape is not required but that latitude for the composition and/or shape is within the scope of the disclosure. It will be understood that these values, compositions, and shapes should be construed as including a manufacturing or operational tolerance (e.g., ±10%) around the stated numerical values, compositions, or shapes.

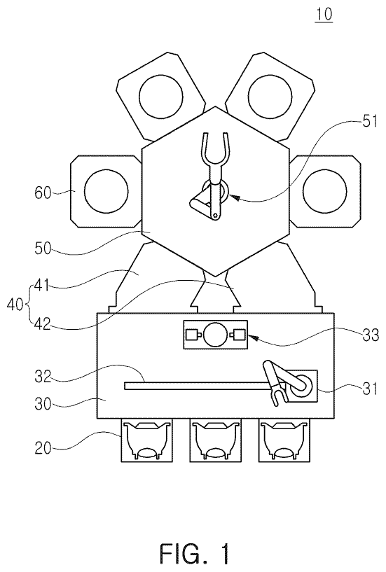

FIG. 1 is a schematic diagram illustrating a semiconductor processing system according to at least one example embodiment of the present inventive concepts.

Referring to FIG. 1, a semiconductor processing system 10 according to at least one example embodiment of the present inventive concepts includes a wafer transfer device 30, a load lock chamber 40, a transfer chamber 50, a plurality of process chambers 60, and/or the like. For example, the wafer transfer device 30 may be configured to receive a wafer through a container (such as a front open unified pod (FOUP) 20) inside a line in which the semiconductor processing system 10 is disposed.

In at least one embodiment, the operation of the semiconductor processing system 10 may be controlled by, e.g., processing circuitry, such as hardware, software, and/or a combination thereof. For example, in at least one embodiment, a controller or controllers (not illustrated) may include processing circuitry configured to control the operation and timing of the wafer transfer device 30, a load lock chamber 40, a transfer chamber 50, a plurality of process chambers 60, and/or the like. For example, more specifically may include (and/or be included in), but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The wafer transfer device 30 may be configured to transfer the wafer received through the FOUP 20 to the load lock chamber 40, and/or receive a wafer on which semiconductor processing has been completed in process chambers 60 from the load lock chamber 40 and store the same in the FOUP 20. The wafer transfer device 30 may include a wafer transfer robot 31 having an arm configured to hold a wafer, a rail unit 32 for moving the wafer transfer robot 31, an aligner 33 for aligning wafers, and/or the like. In at least one example, during the transferring of a wafer from the FOUP 20 to the load lock chamber 40, the wafer transfer robot 31 may remove the wafer stored in the FOUP 20 and place the same on the aligner 33. The aligner 33 may rotate a wafer to align the wafer in a predetermined direction. When wafer alignment is completed in the aligner 33, the wafer transfer robot 31 may remove the wafer from the aligner 33 and transfer the same to the load lock chamber 40.

The load lock chamber 40 may be connected to the wafer transfer device 30, and may include a loading chamber 41 in which wafers inserted into the process chamber 60 temporarily remain inside for semiconductor processing, and an unloading chamber 42 in which wafers removed from the process chamber 60 temporarily remain there inside after the process is completed. When the wafers aligned in the aligner 33 are inserted into the loading chamber 41, the inside of the loading chamber 41 may be depressurized to prevent external contaminants from entering.

The load lock chamber 40 may be connected to the transfer chamber 50, and a plurality of process chambers 60 may be connected around the transfer chamber 50. A wafer transfer robot 51 may be disposed inside the transfer chamber 50 to transfer a wafer between the load lock chamber 40 and the plurality of process chambers 60. The wafer transfer robot 31 of the wafer transfer device 30 may be referred to as a first wafer transfer robot, and the wafer transfer robot 51 of the transfer chamber 50 may be referred to as a second wafer transfer robot.

Each of the plurality of process chambers 60 may perform a semiconductor process on a wafer. For example, a semiconductor process performed by the plurality of process chamber 60 may include a deposition process, an etching process, an exposure process, an annealing process, a polishing process, an ion implantation process, and/or the like.

Plasma may be formed inside at least one of the plurality of process chambers 60 to perform at least a portion of the above-mentioned semiconductor processes. Plasma may be formed on a wafer, a mask, a motherboard for a display, and/or the like, which are targets of a semiconductor process, and plasma may be generated by, for example, a reactive gas supplied to an internal space of an ion beam source mounted in the process chamber 60.

When plasma is formed within the ion beam source, ions in a plasma state can be accelerated to a wafer and/or the like, which is a target of a semiconductor process. For example, ions may be accelerated by a voltage applied to a grid electrode included in an ion beam source, and the voltage applied to the grid electrode may vary according to a polarity of ions present in a plasma state. The grid electrode includes a plurality of through-holes, and the accelerated ions may pass through at least one of the plurality of through-holes. Depending on the embodiment, ions that have passed through the through-hole may lose charge in the process of being reflected after colliding with a reflector, and thus, a neutral beam may be accelerated to a wafer or the like.

However, a collision between the ions and the grid electrode may occur while the ions pass through the through-hole. Particles may be separated from the grid electrode due to the collision with ions, and the separated particles may be combined with the grid electrode again to narrow the through-hole, or the separated particles may fall onto a wafer and cause contamination. For example, damage to the grid electrode due to the collision with ions may be severe depending on the type of reactive gas supplied to form a conductive material and plasma forming the grid electrode. Therefore, usable reactive gas may be limited according to the material properties of the grid electrode included in the semiconductor processing apparatus, and as a result, versatility of the semiconductor processing apparatus may be deteriorated.

In at least one example embodiment of the present inventive concepts, the grid electrode may include a base plate formed of a conductive material, and a cover layer covering the base plate and formed of a dielectric material. Therefore, even when the grid electrode collides with ions, particles of the conductive material may not escape, and problems such as narrowing of the through-hole or contamination of the wafer may be minimized.

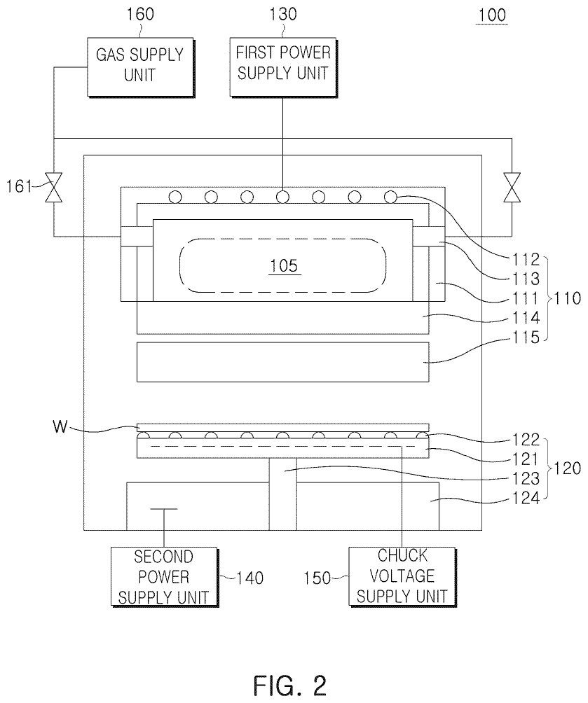

FIG. 2 is a schematic diagram of a semiconductor processing apparatus according to at least one example embodiment of the present inventive concepts.

Referring to FIG. 2, a semiconductor processing apparatus 100 according to at least one example embodiment of the present inventive concepts may include a beam source 110, a process chamber 120, a first power supply unit 130, a second power supply unit 140, a chuck voltage supply unit 150, a gas supply unit 160, and/or the like. The semiconductor processing apparatus 100 may be an apparatus that performs processes such as deposition, etching, and/or the like, using plasma 105 formed in a plasma space provided inside the beam source 110. For example, semiconductor processing apparatus 100 may be at least one of the plurality of process chambers 60 of FIG. 1.

The beam source 110 may include a head 111 in which plasma is formed in a plasma space, a bias electrode 112, a gas flow path 113, a grid electrode 114, a reflector 115, and/or the like.

The process chamber 120 may include an electrostatic chuck 121, a second bias electrode 124, and/or the like, and may be configured such that a processing target to perform a semiconductor process may be seated on the electrostatic chuck 121. In at least one example embodiment illustrated in FIG. 2, the processing target is shown as a wafer W, but the processing target may be changed to a mother substrate for a display, a mask, and/or the like.

As illustrated in FIG. 2, the electrostatic chuck 121 may be fixed to a filler 123, and a plurality of protrusions 122 having a protruding shape may be formed on an upper surface of the electrostatic chuck 121. The wafer W may be seated on the protrusion 122, and thus a space may be formed between the upper surface of the electrostatic chuck 121 and the wafer W. For example, the space between the upper surface of the electrostatic chuck 121 and the wafer W may be filled with a non-reactive gas (e.g., argon gas, helium gas, and/or the like) such that gas cools the wafer W.

In at least one example embodiment, the wafer W may be fixed to the electrostatic chuck 121 by Coulomb forces generated by a chuck voltage supplied to the electrostatic chuck 121. The chuck voltage may be supplied by, e.g., a chuck voltage supply unit 150. For example, the chuck voltage supplied from the chuck voltage supply unit 150 to the electrostatic chuck 121 may be a constant voltage, and may have a magnitude of hundreds to thousands of volts.

In order to perform a semiconductor process, reactive gas may be introduced from the beam source 110 into a plasma space provided inside the head 111 through the gas flow path 113. A valve 161 may first be opened so that the reactive gas may be introduced through the gas flow path 113. The first power supply unit 130 may supply first high frequency (RF) power to a first bias electrode 112 included in the beam source 110, and the second power supply unit 140 may supply second high frequency power to a second bias electrode 124 positioned below the electrostatic chuck 121. Each of the first power supply unit 130 and the second power supply unit 140 may include a high frequency power source for supplying high frequency power. The first power supply unit 130 and the second power supply unit 140 may also be referred to as a first power supply and a second power supply, respectively, and/or as a first voltage supply and a second voltage supply, respectively.

Plasma 105 containing ions, radicals, electrons, and/or the like, of reactive gas may be generated in an internal space of the head 111 of the beam source 110 by first high-frequency power and second high-frequency power, and the reactive gas may be activated by the plasma 105 to increase reactivity. For example, particles included in the plasma 105 may be accelerated by a voltage applied to the grid electrode 114 to collide with the reflector 115, and then move toward the wafer W. When the semiconductor processing apparatus 100 is an etching device, at least a portion of the semiconductor substrate or layers included in the wafer W may be dry etched by particles accelerating toward the wafer W after colliding with the reflector 115.

The grid electrode 114 may include a plurality of through-holes, and particles included in the plasma 105 may be accelerated by an influence of a field generated by a bias voltage applied to the grid electrode 114, and may pass through the plurality of through-holes. In at least one example embodiment, the particles passing through the plurality of through-holes may be neutralized by charge exchange with the reflector 115 in a process of colliding with the reflector 115, and as a result, the beam source 110 may emit a neutral beam moving toward the wafer W.

The neutral beam may have higher linearity than the ion beam due to charged particles, and therefore, the reliability of the semiconductor process may be improved by using the beam source 110 emitting the neutral beam. However, as discussed above, before being neutralized the charged particles may collide with the grid electrode 114 while passing through the through-holes of the grid electrode 114, and the grid electrode 114 may be damaged by the collision of the ions and the grid electrode 114. When the grid electrode 114 is damaged, particles escaping from the grid electrode 114 may fall onto the wafer W and cause a contamination issue, and/or may become attached to the grid electrode 114 again thereby reducing the area of the through-holes.

The above-described issues may become severe depending on the type of conductive material constituting the grid electrode 114 and the type of reactive gas provided by the gas supply unit 160. As a result, the type of reactive gas may be limited according to the material of the grid electrode 114, which may degrade the versatility of the semiconductor processing apparatus 100. The gas supply unit may also be referred to as a gas supply.

In at least one example embodiment of the present inventive concepts, in order to solve the above-described issues, the grid electrode 114 may include a base plate formed of a conductive material and a cover layer covering at least a portion of the surface of the base plate. Unlike the base plate, the cover layer may be formed of a dielectric material. For example, the based plate may be formed of, for example, Y₂O₃, Al₂O₃, and/or the like. By forming a cover layer on at least a portion of a surface of the base plate, even when particles accelerating toward the grid electrode 114 collide with the grid electrode 114, damage to the grid electrode 114 may be minimized and/or prevented.

According to some example embodiments, the cover layer may have a stacked structure including a plurality of layers. For example, the cover layer may include a first cover layer and a second cover layer, sequentially stacked from the surface of the base plate. The first cover layer and the second cover layer may be formed of different dielectric materials.

Meanwhile, in at least one example embodiment of the present inventive concepts, a voltage having a predetermined (or alternatively desired) cycle may be applied to the grid electrode 114 as a bias voltage instead of a constant voltage. By applying a voltage having a waveform such as a square wave, a sawtooth wave, or the like, to the grid electrode 114, regardless of a material and structure of the grid electrode 114, a field sufficient to accelerate particles included in the plasma 105 can be formed around the grid electrode 114.

According to the embodiment, the grid electrode 114 may include a first grid electrode and a second grid electrode disposed in a direction from the head 111 toward the electrostatic chuck 121. In at least one example embodiment of the present inventive concepts, a voltage having a cycle such as a square wave, a sawtooth wave, a triangular wave, or the like, may be input to one of the first grid electrode and the second grid electrode, and a constant voltage may be input to the other one thereof to form a field around the grid electrode 114, and particles of the plasma 105 may be accelerated toward the electrostatic chuck 121.

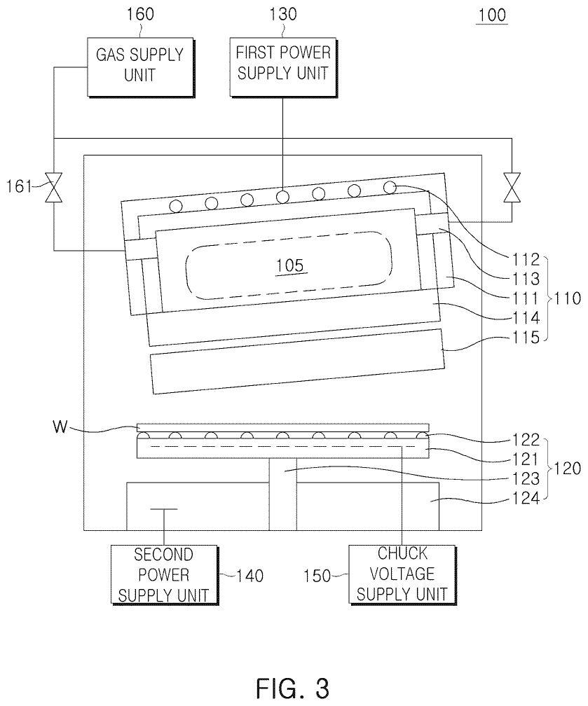

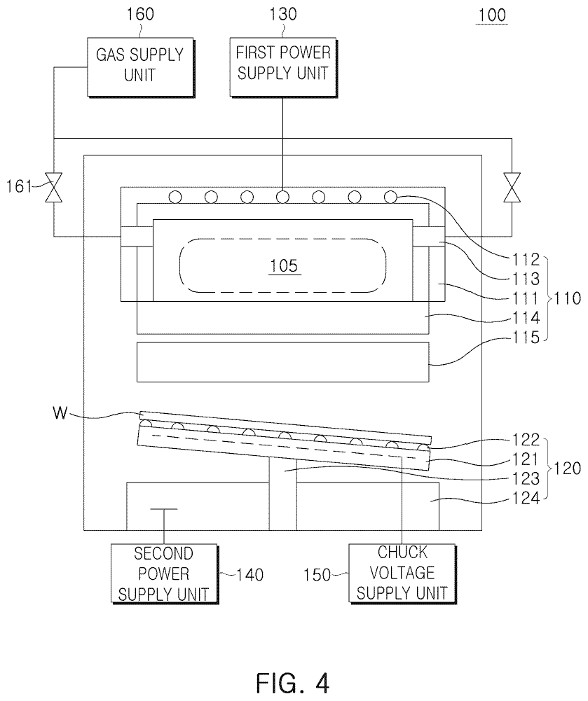

FIGS. 3 and 4 are diagrams provided to illustrate an operation of a semiconductor processing apparatus according to at least one example embodiment of the present inventive concepts.

FIGS. 3 and 4 may be diagrams provided for illustrating an operation of a semiconductor processing apparatus 100 to accurately propagate a neutral beam emitted from the beam source 110 and having linearity to a target region of the wafer W. In the embodiment illustrated in FIG. 3, an emission angle of the neutral beam may be adjusted by moving the beam source 110, and in the embodiment illustrated in FIG. 4, a direction of the wafer W may be changed by moving the electrostatic chuck 121.

In at least one example embodiment, the reflector 115 included in the beam source 110 may include a plurality of reflection structures disposed to be inclined in a predetermined (or alternatively desired) direction. Particles passing through the plurality of through-holes included in the grid electrode 114 may move toward the wafer W after being reflected at least once in a space between the plurality of reflective structures.

Accordingly, a traveling direction of the neutral beam emitted from the beam source 110 may be determined by an incident angle of particles incident on the reflector 115 and a reflection angle of particles reflected by the reflector 115. In example embodiments of the present inventive concepts, as illustrated in FIGS. 3 and 4, at least one of the beam source 110 and the electrostatic chuck 121 may be moved to align the traveling direction of the neutral beam emitted from the beam source 110 and the wafer W.

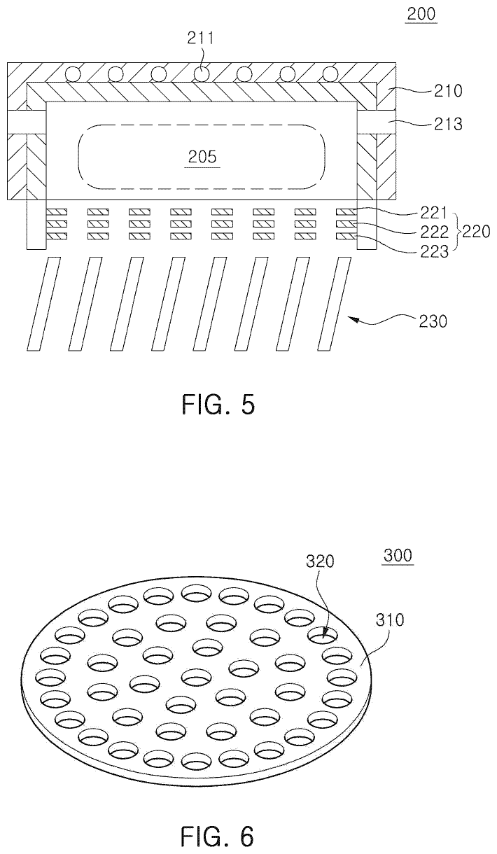

FIG. 5 is a diagram schematically illustrating a beam source included in a semiconductor processing apparatus according to at least one example embodiment of the present inventive concepts.

Referring to FIG. 5, a beam source 200 according to at least one example embodiment of the present inventive concepts may include a head 210, a first bias electrode 211, a gas flow path 213, a grid electrode 220, and a reflector 230. Reactive gas may be supplied through the gas flow path 213, and plasma 205 may be generated by high frequency power applied to the first bias electrode 211.

In at least one example embodiment illustrated in FIG. 5, the grid electrode 220 may include a first grid electrode 221, a second grid electrode 222, a third grid electrode 223, and/or the like, and each of the first to third grid electrodes 221 to 223 may include a plurality of through-holes. In at least one example embodiment, the plurality of through-holes included in each of the first to third grid electrodes 221 to 223 may be aligned to allow particles moving from the plasma 205 to pass therethrough. A reflector 230 may be disposed below the plurality of through-holes, and the reflector 230 may include a plurality of reflective structures.

Different bias voltages may be applied to at least a portion of the first to third grid electrodes 221 to 223, and the voltage applied to each of the first to third grid electrodes 221 to 223 may vary depending on the type of particles present in the plasma 205. For example, when a plurality of positive ions is present in the plasma 205, a positive voltage may be applied to the first grid electrode 221 as a first bias voltage, a negative voltage may be applied to the second grid electrode 222 as a second bias voltage, and a ground voltage may be applied to the third grid electrode 223 as a third bias voltage. Therefore, positive ions may be accelerated by a field generated between the first grid electrode 221 and the second grid electrode 222, and the positive ions lose charges and are neutralized in a process of colliding with the reflector 230, thereby emitting a neutral beam.

In at least one example embodiment of the present inventive concepts, particles accelerating from the plasma 205 and passing through-holes collide with the grid electrode 220, and as a result, the grid electrode 220 may have a structure including a base plate and a cover layer so that the particles do not escape from the grid electrode 220. The base plate may be formed of a conductive material capable of applying a bias voltage, and the cover layer may be formed of a metal oxide covering at least a portion of the surface of the base plate.

Since the grid electrode 220 includes a cover layer, a field sufficient to accelerate particles of the plasma 205 may not be formed by the grid electrode 220 only by applying a constant voltage as a bias voltage to the grid electrode 220. Therefore, in at least one example embodiment of the present inventive concepts, a voltage having a predetermined (or alternatively desired) cycle may be applied as a bias voltage to at least one of the first to third grid electrodes 221 to 223. To this end, the voltage supply unit connected to the grid electrode 220 may include a circuit for generating voltages of various waveforms.

In addition, according to example embodiments, a bias voltage may be applied to the reflector 230. In at least one example embodiment of the present inventive concepts, the bias voltage applied to the reflector 230 may also be generated as a voltage having a predetermined cycle rather than a constant voltage.

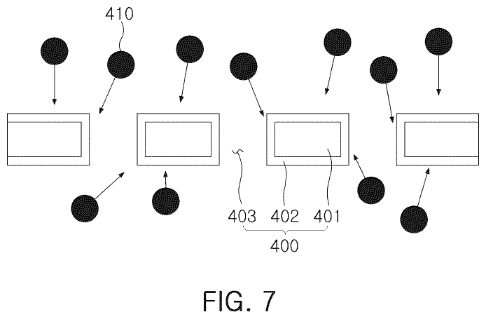

FIGS. 6 and 7 are diagrams schematically illustrating a grid electrode according to at least one example embodiment of the present inventive concepts.

Referring first to FIG. 6, a grid electrode 300 according to at least one example embodiment of the present inventive concepts may include a plate 310 and a plurality of through-holes 320. The grid electrode 300 may be, for example, at least one of the grid electrode 220 and/or the grid electrode 114. Although the plurality of through-holes 320 are illustrated in a circular shape, this is merely an example, and a shape of the plurality of through-holes 320 may be variously modified. As described above, the plate 310 may include a base plate formed of a conductive material (e.g., base plate 401 of FIG. 7) and a cover layer formed of a dielectric material (e.g., the cover layer 402 of FIG. 7) such as metal oxide. Accordingly, particles accelerating from the plasma may not directly collide with the base plate formed of a conductive material.

Referring to FIG. 7, the grid electrode 400 may include a base plate 401, a cover layer 402 surrounding the base plate 402, and a plurality of through-holes 403. Particles 410 present in plasma may be accelerated as illustrated in FIG. 7 by an influence of a field generated by a bias voltage applied to the grid electrode 400. A portion of the particles 410 may pass through the plurality of through-holes 403, but the other portion of the particles may collide with the grid electrode 400.

In a structure in which the base plate 401 formed of a conductive material, for example, metal, is directly exposed externally without the cover layer 402, metal particles may be separated from the base plate 401 by an impact received from the accelerating particles 410. The separated metal particles may be attached to the base plate 401 again by metal bonding to reduce an area of through-holes 403. Alternatively, the separated metal particles may fall as they are to a processing target such as a wafer located below the grid electrode 400, which may cause a contamination issue.

In particular, the amount of metal particles generated may increase according to a material of the base plate 401 and the type of reactive gas supplied to form plasma. For example, when sulfur hexafluoride (SF₆) and carbon tetrafluoride (CF₄) are used as reaction gases for the base plate 401 formed of molybdenum (Mo), the base plate 401 is etched to form metal particles when exposed externally without the cover layer 402.

In at least one example embodiment of the present inventive concepts, the above-described problem may be solved by forming a cover layer 402 of a dielectric material, for example, metal oxide, on a surface of the base plate 401. Due to the cover layer 402, the base plate 401 may not directly collide with the particles 410. Therefore, regardless of the type of metal material forming the base plate 401, plasma may be generated using various reactive gases and a semiconductor process may be performed, and versatility of the semiconductor processing apparatus may be improved.

The cover layer 402 may be formed to cover an entire surface of the base plate 401, or to cover only a portion of the surface of the base plate 401. For example, in at least one example the cover layer 402 may cover only a portion of the surface of the base plate 401 exposed to the acceleration path of the particles due to, e.g., the influence of the field generated by the bias voltage applied to the grid electrode. The cover layer 402 may be formed of a metal oxide such as Y₂O₃, Al₂O₃, and/or the like.

The cover layer 402 in contact with the base plate 401 may result in the grid electrode functioning as a capacitor having a predetermined (or alternatively desired) capacitance. Therefore, when a constant voltage is applied as a bias voltage to the base plate 401, a field capable of accelerating the particles 410 may not be formed. In at least one example embodiment of the present inventive concepts, a field accelerating the particles 410 may be formed around the grid electrode 400 by applying a voltage having a waveform such as a square wave, a sawtooth wave, and/or the like, to the base plate 401 as a bias voltage.

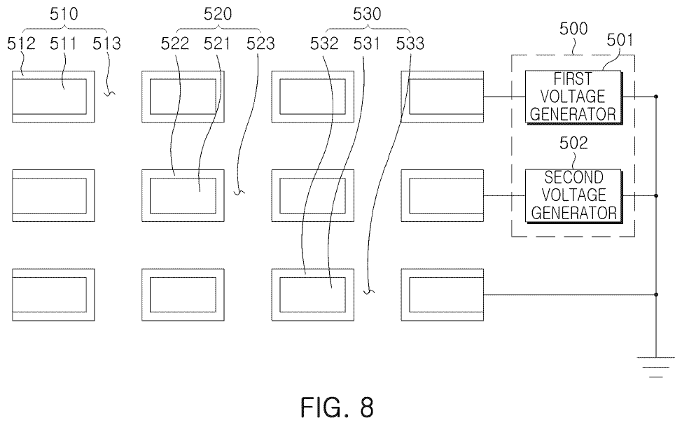

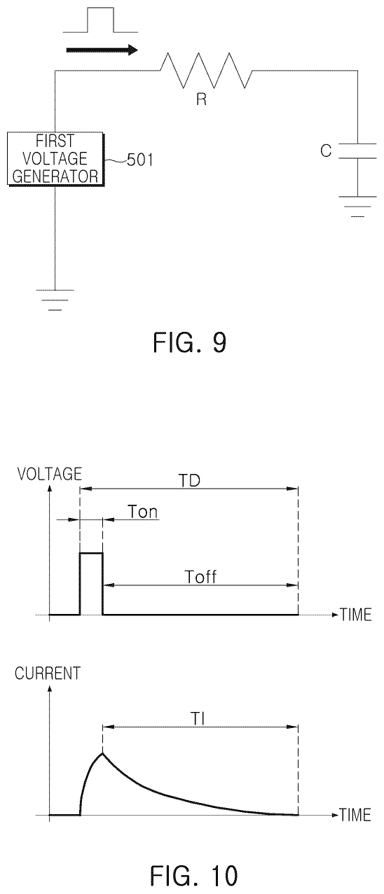

FIGS. 8 and 9 are diagrams provided to illustrate an operation of a semiconductor processing apparatus according to at least one example embodiment of the present inventive concepts.

Referring first to FIG. 8, a semiconductor processing apparatus according to at least one example embodiment of the present inventive concepts may include a voltage supply unit 500 and a plurality of grid electrodes 510 to 530. The voltage supply unit 500 may apply a predetermined (or alternatively desired) bias voltage to each of the plurality of grid electrodes 510 to 530. In the embodiment illustrated in FIG. 8, the plurality of grid electrodes 510 to 530 may include first to third grid electrodes 510 to 530, a first voltage generator 501 may be connected to the first grid electrode 510, and a second voltage generator 502 may be connected to the second grid electrode 520. However, the number of the plurality of grid electrodes 510 to 530 and the configuration of the voltage supply unit 500 may be variously modified according to the example embodiments.

Each of the plurality of grid electrodes 510 to 530 may have a similar structure. For example, the first grid electrode 510 may include a base plate 511, a cover layer 512, and a plurality of through-holes 513, and the second grid electrode 520 may include a base plate 521, a cover layer 522, and a plurality of through-holes 523. The third grid electrode 530 may also include a base plate 531, a cover layer 532, and a plurality of through-holes 533. Alternatively, according to example embodiments, at least one grid electrode having a low probability of collision with particles accelerating from plasma, for example, the third grid electrode 530 may not include the cover layer 532 in some example embodiments.

The first voltage generator 501 may output a first bias voltage to the base plate 511 of the first grid electrode 510, and the second voltage generator 502 may output a second bias voltage to the base plate 521 of the second grid electrode 520. Meanwhile, in the embodiment illustrated in FIG. 8, a ground voltage may be input to a third bias voltage to the base plate 531 of the third grid electrode 530. Alternatively, a third bias voltage (e.g., other than the ground voltage) may also be input to the third grid electrode 530 according to some example embodiments.

In at least one example embodiment of the present inventive concepts, at least one of the first bias voltage and the second bias voltage may be a variable voltage (e.g., not a constant voltage). For example, the first voltage generator 501 may output a first bias voltage having a waveform such as a square wave, a sawtooth wave, a triangular wave, and/or the like, and the second voltage generator 502 may output a second bias voltage, a constant voltage. Alternatively, the first voltage generator 501 may output a first bias voltage, a constant voltage, and the second voltage generator 502 may output a second bias voltage having a waveform such as a square wave, a sawtooth wave, a triangular wave, or the like. Alternatively, each of the first voltage generator 501 and the second voltage generator 502 may output a voltage having a waveform such as a square wave, a sawtooth wave, a triangular wave, and/or the like.

A level of each of the first bias voltage and the second bias voltage may vary depending on the type of a plurality of ions present in plasma. For example, when a plurality of positive ions are present in the plasma, the first bias voltage may be generated as a positive voltage, and the second bias voltage may be generated as a ground voltage or a negative voltage. In at least some embodiments, the level of each of the first bias voltage and the second vias voltage may be hundreds of kV.

FIG. 9 may be an equivalent circuit diagram simply illustrating a first voltage generator 501 and a first grid electrode 510. Referring to FIG. 9, the first grid electrode 510 may be represented by a resistance element R and a capacitor element C connected to the first voltage generator 501. The resistor element R may correspond to the base plate 511 of the first grid electrode 510, and the capacitor element C may correspond to the cover layer 512 of the first grid electrode 510. The capacitance of the capacitor element C may be determined according to a material of the cover layer 512 and a shape of the cover layer 512.

The first voltage generator 501 may output a voltage having a predetermined (or alternatively desired) cycle, such as a square wave, a sawtooth wave, a triangular wave, and/or the like, as a first bias voltage. Therefore, a displacement current and a field may be generated according to a time constant of an RC series circuit including the resistor element R and the capacitor element C, and ions included in the plasma may be accelerated by an influence of the field.

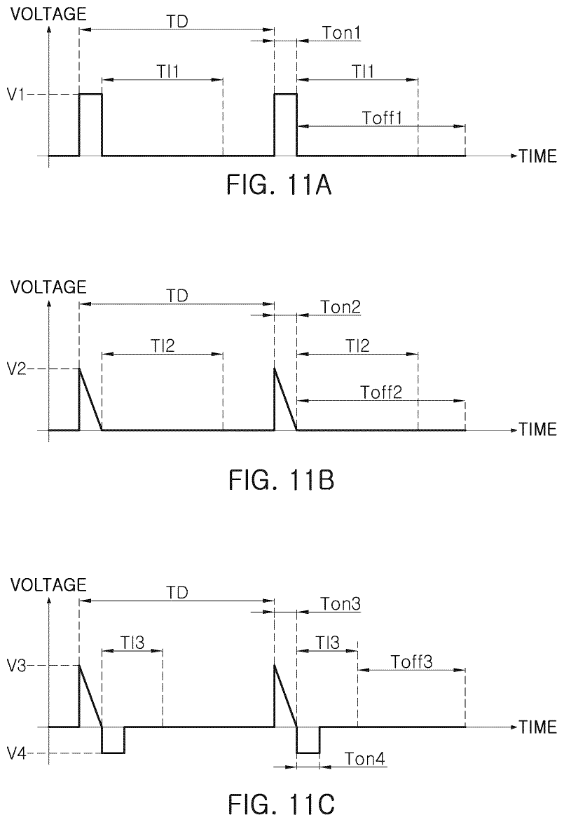

FIGS. 10 and 11 are diagrams provided to illustrate an operation of a semiconductor processing apparatus according to at least one example embodiment of the present inventive concepts.

FIG. 10 may be a diagram illustrating a bias voltage applied to at least one of a plurality of grid electrodes included in a semiconductor processing apparatus and a current generated thereby. Referring to FIG. 10, a square wave bias voltage having a predetermined cycle (TD) may be applied to at least one grid electrode and the time scale of the diagrams are equivalent to each other. The bias voltage may have a first level V1 during an on-time (Ton) of one cycle and a ground level during an off-time (Toff).

In at least one example embodiment of the present inventive concepts, the grid electrode may include a base plate formed of a conductive material and a cover layer formed on a surface of the base plate. The cover layer may be formed of a dielectric material, and thus, as described above with reference to FIG. 9, the grid electrode may be expressed as an equivalent circuit including a resistor element and a capacitor element.

During the on-time (Ton) during which a voltage of the first level V1 is applied, a capacitor element provided by the cover layer may be charged. In addition, during the off-time (Toff), charges charged in the capacitor element may be discharged. As described above, the capacitor element corresponding to the cover layer may be charged and discharged repeatedly by a bias voltage, and an acceleration time (TI) for accelerating the particles included in the plasma may be included in a time during which charges charged in the cover layer are discharged.

FIGS. 11A through 11C include graphs illustrating a bias voltage that may be applied to a grid electrode by a voltage supply unit, in a semiconductor processing apparatus according to at least one example embodiment of the present inventive concepts. However, the voltage applied to the grid electrode may have a waveform other than those illustrated in the graphs of FIGS. 11A through 11C.

First, referring to the graph of FIG. 11A, the bias voltage applied by the voltage supply unit to the grid electrode may be a rectangular shape. The bias voltage is a voltage having a predetermined cycle TD, may have a first level V1 during a first on-time (Ton1) and a ground level during a first off-time (Toff1). A first acceleration time (TI1) in which particles such as ions included in the plasma acceleration may be included in the first off time Toff1. However, according to example embodiments, the first acceleration time TI1 may overlap the first on-time (Ton1) and the first off-time (Toff1).

Next, referring to the graph of FIG. 11B, a bias voltage applied to the grid electrode by the voltage supply unit may be a sawtooth wave. The bias voltage may increase to a second level V2 during a second on-time (Ton2) of a cycle TD and then decrease, and may be maintained at a ground level during a second off-time (Toff2). A second acceleration time TI2 during which plasma particles are accelerated may be included in the second off-time (Toff2), and according to example embodiments, the second acceleration time TI2 may start during the second on-time (Ton2) during which the bias voltage decreases.

Next, referring to the graph of FIG. 11C, a bias voltage applied to the grid electrode by the voltage supply unit may have a waveform in which a sawtooth wave and a square wave are mixed. The bias voltage may have a sawtooth waveform that increases to a third level V3 and then decreases during a third on-time (Ton3) of a cycle TD, and have a square wave waveform having a fourth level V4 during a fourth on-time (Ton4). During the fourth on-time (Ton4), the bias voltage may have a negative level. Meanwhile, the bias voltage may be maintained at a ground level during the third off-time (Toff3).

By applying the bias voltage of the waveform as illustrated in the graph of FIG. 11 C to the grid electrode, charges charged in the cover layer included in the grid electrode can be more rapidly discharged, and the field strength can be increased. However, since the charge is rapidly discharged, the third acceleration time TI3 during which plasma particles are accelerated may be shorter than the first acceleration time TI1 and the second acceleration time TI2.

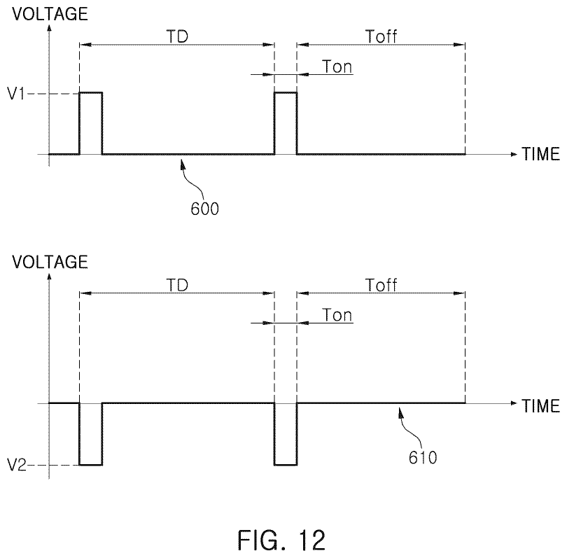

FIGS. 12 to 14 are views provided to illustrate an operation of a semiconductor processing apparatus according to at least one example embodiment of the present inventive concepts.

FIGS. 12 to 14 may be diagrams illustrating waveforms of a first bias voltage applied to a first grid electrode included in a semiconductor processing apparatus and a second bias voltage applied to a second grid electrode. In a semiconductor processing apparatus, the first grid electrode and the second grid electrode are sequentially disposed, and for example, the second grid electrode may be disposed closer to an electrostatic chuck than to the first grid electrode.

First, referring to FIG. 12, each of a first bias voltage 600 and a second bias voltage 610 may be a square wave having a predetermined (or alternatively desired) cycle TD. The first bias voltage 600 and the second bias voltage 610 may have opposite phases. For example, the first bias voltage 600 may have a first level V1 during an on-time Ton, and the second bias voltage 610 may have a second level V2 during an on-time Ton. The first level V1 and the second level V2 may have the same magnitude but opposite signs, and both the first bias voltage 600 and the second bias voltage 610 may have a ground level during an off-time Toff.

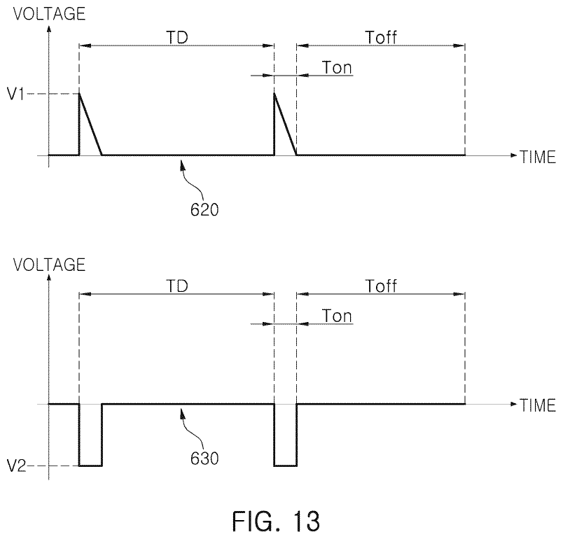

Next, referring to FIG. 13, the first bias voltage 620 may be a sawtooth wave and the second bias voltage 630 may be a square wave. During an on-time Ton of a cycle TD, a first bias voltage 620 may have a level increasing to a first level V1 and then decreasing, and the second bias voltage 630 may be maintained at a second level V2. During an off time Toff, both the first bias voltage 620 and the second bias voltage 630 may be maintained at a ground level.

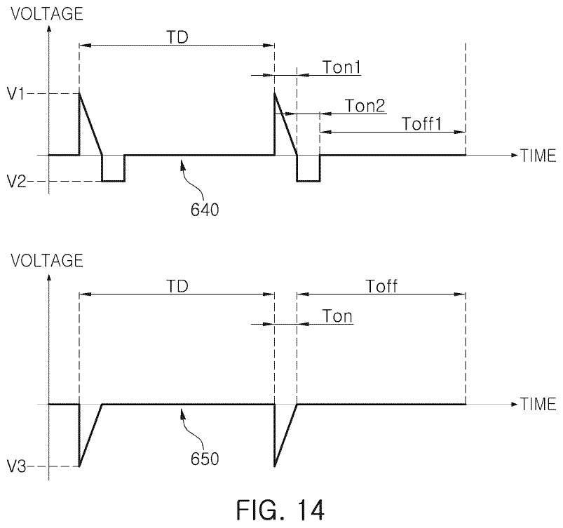

Referring to FIG. 14, a first bias voltage 640 may be a voltage having a waveform in which a sawtooth wave and a square wave are mixed, and the second bias voltage 650 may have a sawtooth wave. The first bias voltage 640 may increase to a first level V1 during a first on-time Ton1 of a cycle TD, then decrease, and may be maintained at a second level V2, lower than a ground level during a second on-time Ton2. A second bias voltage 650 may decrease to a third level V3, lower than a ground level during an on-time Ton of a cycle TD and then increase. The first off-time Toff1 at which the first bias voltage 640 is maintained at a ground level may be shorter than the off-time Toff at which the second bias voltage 650 is maintained at a ground level.

When a plurality of positive ions are present in plasma generated in the semiconductor processing apparatus, bias voltages according to the embodiments described with reference to FIGS. 12 to 14 may be applied to a first grid electrode and a second grid electrode to accelerate the positive ions to an electrostatic chuck. When a plurality of negative ions are present in the plasma, on the contrary, a first bias voltage having a negative voltage may be applied to the first grid electrode and a second bias voltage having a positive voltage may be applied to the second grid electrode to accelerate the negative ions to the electrostatic chuck.

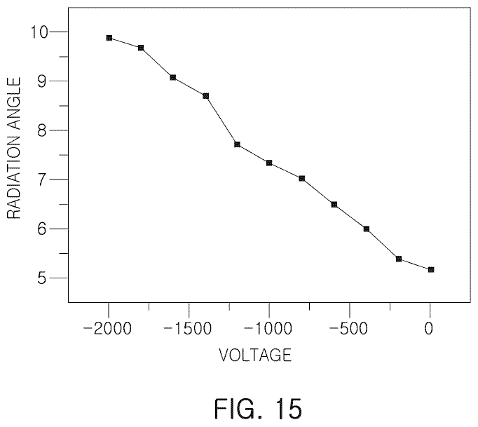

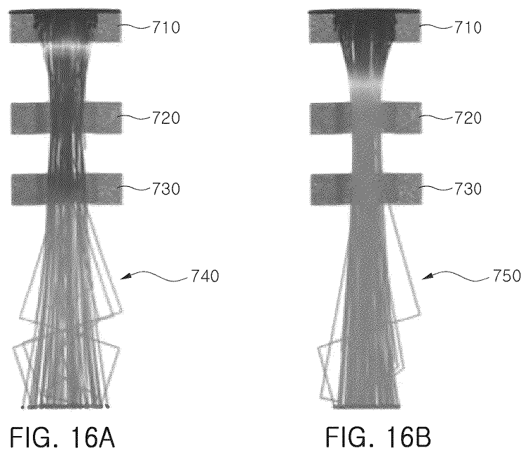

FIGS. 15 and 16A through 16B are diagrams provided to illustrate an operation of a semiconductor processing apparatus according to at least one example embodiment of the present inventive concepts.

In at least one example embodiment described with reference to FIGS. 15 and 16A through 16B, the semiconductor processing apparatus may include a first grid electrode 710, a second grid electrode 720, and a third grid electrode 730, and plasma may include a plurality of positive ions. The first grid electrode 710, the second grid electrode 720, and the third grid electrode 730 may be the same as and/or substantially similar to the first grid electrode 510, the second grid electrode 520, and the third grid electrode 530 of FIG. 8. Plasma may be generated in a space above the first grid electrode 710, and an electrostatic chuck may be positioned below the third grid electrode 730. Plasma generated in a space above the first grid electrode 710 may include a plurality of positive ions, and a negative voltage may be applied to at least one of the second grid electrode 720 and the third grid electrode 730, so that the positive ions can be sufficiently accelerated toward the electrostatic chuck. Hereinafter, for convenience of explanation, it will be taken that an inverse negative voltage is applied to the second grid electrode 720.

FIG. 15 may be a graph illustrating a relationship between a voltage applied to the second grid electrode 720 and a radiation angle of an electron beam passing through the grid electrodes 710 to 730. Referring to FIG. 15, as an absolute value of the bias voltage applied to the second grid electrode 720 increases, the radiation angle of the electron beam may increase.

FIG. 16A may be a diagram illustrating a traveling path of an electron beam 740 passing through grid electrodes 710 to 730 when a bias voltage of −2000 V is applied to the second grid electrode 720. Meanwhile, FIG. 16B may be a diagram illustrating a traveling path of an electron beam 750 passing through grid electrodes 710 to 730 when a bias voltage of 0 V is applied to the second grid electrode 720.

As illustrated in FIG. 16, as an absolute value of a negative voltage applied to the second grid electrode 720 increases, radiation angles of electron beams 740 and 750 may increase. Accordingly, in the semiconductor processing apparatus according to at least one example embodiment of the present inventive concepts, a degree of concentration of the electron beams 740 and 750 may be changed by adjusting the bias voltage applied to the second grid electrode 720.

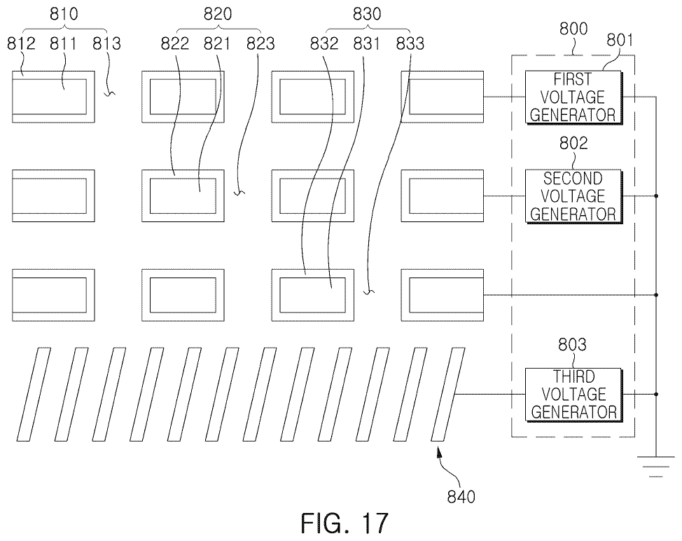

FIG. 17 is a diagram provided to illustrate an operation of a semiconductor processing apparatus according to at least one example embodiment of the present inventive concepts.

Referring to FIG. 17, a semiconductor processing apparatus according to at least one example embodiment may include a voltage supply unit 800, a plurality of grid electrodes 810 to 830, a reflector 840, and/or the like. The voltage supply unit 800 may be configured to apply a predetermined bias voltage to each of the plurality of grid electrodes 810 to 830 and the reflector 840. In at least one example embodiment illustrated in FIG. 17, a first voltage generator 801 may be connected to the first grid electrode 810 and a second voltage generator 802 may be connected to the second grid electrode 820.

Each of the plurality of grid electrodes 810 to 830 may have a similar structure. For example, the first grid electrode 810 may include a base plate 811, a cover layer 812, and a plurality of through-holes 813, and the second grid electrode 820 may include a base plate 821, the cover layer 822, and a plurality of through-holes 823. The third grid electrode 830 may also include a base plate 831, a cover layer 832, and a plurality of through-holes 833. However, according to some example embodiments, at least one grid electrode having a low probability of collision with particles accelerating from plasma, for example, the third grid electrode 830 may not include a cover layer 832.

The first voltage generator 801 may output a first bias voltage to the base plate 811 of the first grid electrode 810, and the second voltage generator 802 may output a second bias voltage to the base plate 821 of the second grid electrode 820. A ground voltage may be input as a third bias voltage to the base plate 831 of the third grid electrode 830.

At least one of the first bias voltage and the second bias voltage is not a constant voltage, and may have, for example, a waveform such as a square wave, a sawtooth wave, a triangular wave, or the like. In addition, in the embodiment illustrated in FIG. 17, a bias voltage may be input to the reflector 840 by a third voltage generator 803. For example, the third voltage generator 803 may input a bias voltage having a waveform such as a square wave, a sawtooth wave, a triangular wave, or the like, to the reflector 840.

As set forth above, according to at least one example embodiment of the present inventive concepts, a grid electrode may include a base electrode formed of a conductive material, and a cover layer formed of a metal oxide on a surface of the base plate.

Therefore, despite collisions with ions accelerated by a voltage applied to the grid electrode in a plasma state, particles separated from the grid electrode may be minimized to improve yield in a semiconductor process and a lifespan and reliability of a semiconductor processing apparatus.

In addition, by forming the cover layer, since a semiconductor process can be performed, regardless of the type of gas for forming plasma and the type of conductive material constituting the base plate, versatility of the semiconductor processing apparatus can be improved.

The various and advantageous advantages and effects of the present inventive concepts are not limited to the above description, and may be more easily understood in the course of describing the specific embodiments of the present inventive concepts. While example embodiments have been shown and described above, it will be apparent to those skilled in the art that modifications and variations could be made without departing from the scope of the present inventive concepts, as defined by the appended claims.

While example embodiments have been shown and described above, it will be apparent to those skilled in the art that modifications and variations could be made without departing from the scope of the present inventive concepts as defined by the appended claims.

What is claimed is:

1. A semiconductor processing apparatus, comprising:
a chamber defining an internal space;
an electrostatic chuck included in the internal space of the chamber;
a plurality of grid electrodes above the electrostatic chuck, the plurality of grid electrodes spaced apart from each other in a vertical direction and respectively having a plurality of through-holes;
a plurality of reflectors between the plurality of grid electrodes and the electrostatic chuck, the plurality of reflectors configured to reflect ions passing through the plurality of through-holes of each of the plurality of grid electrodes; and
at least one voltage supply configured to output a bias voltage having a cycle to at least one of the plurality of grid electrodes,
wherein each of the plurality of grid electrodes includes
a base plate comprising a conductive material, and
a cover layer covering a surface of the base plate and comprising a metal oxide.

2. The semiconductor processing apparatus of claim 1, wherein the metal oxide dielectric comprises at least one of Y₂O₃ and Al₂O₃.

3. The semiconductor processing apparatus of claim 1, wherein the cover layer comprises at least a first cover layer and a second cover layer.

4. The semiconductor processing apparatus of claim 1, wherein a thickness of the cover layer, as measured from one surface of the base plate is smaller than a corresponding thickness of the base plate.

5. The semiconductor processing apparatus of claim 1, wherein the at least one voltage supply is configured to output the bias voltage such that the bias voltage has a positive voltage level during a first time in the cycle, and has a ground level during a second time, different from the first time, in the cycle.

6. The semiconductor processing apparatus of claim 5, wherein the bias voltage has a waveform of at least one of a square wave or a saw wave.

7. The semiconductor processing apparatus of claim 1, wherein the at least one voltage supply is configured to output the bias voltage such that the bias voltage has
a positive voltage level during a first time in the cycle,
a negative voltage level during a second time, different from the first time in the cycle, and
a ground level during a third time, different from the first time and the second time in the cycle.

8. The semiconductor processing apparatus of claim 1, wherein
the plurality of grid electrodes comprises at least a first grid electrode and a second grid electrode between the first grid electrode and the electrostatic chuck, and
the at least one voltage supply is configured to output a first bias voltage to the first grid electrode and output a second bias voltage, different from the first bias voltage, to the second grid electrode.

9. The semiconductor processing apparatus of claim 8, wherein the at least one voltage supply is configured to output the first bias voltage as the bias voltage having the cycle, and to output the second bias voltage as a constant voltage less than a ground level.

10. The semiconductor processing apparatus of claim 8, wherein the at least one voltage supply is configured to output the first bias voltage as a constant voltage, higher than a ground level, and to output the second bias voltage as the bias voltage having the cycle.

11. The semiconductor processing apparatus of claim 8, wherein the at least one voltage supply is configured to output the first bias voltage as a voltage having a first cycle, and to output the second bias voltage as a voltage having a second cycle.

12. The semiconductor processing apparatus of claim 11, wherein the first bias voltage has a positive voltage level in at least a portion of the first cycle, and the second bias voltage has a negative voltage level in at least a portion of the second cycle.

13. The semiconductor processing apparatus of claim 8, wherein the plurality of grid electrodes further comprises a third grid electrode between the second grid electrode and the electrostatic chuck, and
the voltage supply is configured to output at least one of a third bias voltage or a ground voltage to the third grid electrode.

14. A semiconductor processing apparatus, comprising:
an electrostatic chuck included in an internal space of a chamber;
a beam source including a head defining a plasma space configured for process gas to be supplied to, a bias electrode on the head and configured to receive radio frequency (RF) power, and at least one grid electrode below the head, the at least one grid electrode each having a plurality of through-holes; and
a gas supply configured to supply the process gas to the beam source,
wherein the at least one grid electrode includes a base plate comprising a first material having conductivity, and a cover layer covering a surface of the base plate and comprising a second material, different from the first material.

15. The semiconductor processing apparatus of claim 14, further comprising:
a voltage supply,
wherein the at least one grid electrode comprises a plurality of grid electrodes, and
the voltage supply is configured to supply a bias voltage having a cycle to at least one grid electrode, from among the plurality of grid electrodes, and to supply a DC voltage having a constant voltage level to another grid electrode, from among the plurality of grid electrodes.

16. The semiconductor processing apparatus of claim 15, wherein the another grid electrode is between the at least one grid electrode configured to be supplied with the bias voltage and the electrostatic chuck.

17. The semiconductor processing apparatus of claim 15, wherein the cycle comprises
a first time at which the bias voltage has a voltage level, different from a ground level, and
a second time at which the bias voltage has the ground level, and
wherein the voltage supply is configured to determine the voltage level based on the process gas.

18. The semiconductor processing apparatus of claim 14, wherein the second material contains a metal oxide dielectric.

19. A semiconductor processing apparatus, comprising:
an electrostatic chuck included in an internal space of a chamber;
a beam source including a head defining a plasma space configured for process gas to be supplied to, a bias electrode on the head and configured to receive radio frequency (RF) power, and a plurality of grid electrodes below the head, the plurality of grid electrodes each respectively including a plurality of through-holes;
a gas supply configured to supply the process gas; and
at least one voltage supply configured to supply, to each of the plurality of grid electrodes, a bias voltage,
wherein the voltage supply is configured to supply a voltage having a cycle to at least one of the plurality of grid electrodes, and to supply a constant voltage to another of the plurality of grid electrodes.

20. The semiconductor processing apparatus of claim 19, wherein the plurality of grid electrodes comprises
a first grid electrode, and
a second grid electrode between the first grid electrode and the electrostatic chuck, and
the at least one voltage supply is configured to supply the voltage having the cycle to the first grid electrode, and to supply the constant voltage to the second grid electrode.
